(19) United States
(12) Patent Application Publication
(10) Pub. No.: US 2011/0198609 A1
(43) Pub. Date: Aug. 18, 2011

(54) Light-Emitting Devices with Through-Substrate Via Connections

(75) Inventor: Hsin-Chieh Huang, Hsin-Chu (TW)

(73) Assignee: Taiwan Semiconductor Manufacturing Company, Ltd., Hsin-Chu (TW)

(21) Appl. No.: 12/704,974

(22) Filed: Feb. 12, 2010

(51) Int. Cl. H01L 33/30; H01L 33/48; H01L 33/00; H01L 33/62

(52) U.S. Cl. 257/76; 257/99; 438/42; 257/103; 257/E33.005; 257/E33.023; 257/E33.056; 257/E33.066

(57) ABSTRACT

Multiple through-substrate vias (TSVs) are used to make electrical connections for an LED formed over a substrate. A first TSV extends through the substrate from a back surface of the substrate to the front surface of the substrate and includes a first TSV conductor that electrically connects to a first cladding layer of the LED. A second TSV extends through the substrate and an active layer of the LED from the back surface of the substrate to a second cladding layer or an ITO layer. The second TSV includes an isolation layer that electrically isolates a second TSV conductor from the first cladding layer and the active layer. Additionally dummy TSVs may be formed to conduct heat away from the LED optionally through a package substrate.

### TECHNICAL FIELD

This disclosure relates generally to integrated circuits, and more particularly to integrated circuits comprising LEDs with through-substrate via connections.

### BACKGROUND

In recent years, optical devices, such as light-emitting diodes, laser diodes, and UV photo-detectors have increasingly been used. Group-III/V compounds, such as gallium nitride (GaN), GaAsP, GaPN, AlInGaAs, GaAsPN, AlGaAs, and their respective alloys, have been suitable for the formation of the optical devices. The large bandgap and high electron saturation velocity of the group-III/V compounds also make them excellent candidates for applications in high-temperature and high-speed power electronics.

Due to the high equilibrium pressure of nitrogen at typical growth temperatures, it is difficult to obtain GaN bulk crystals. Therefore, GaN layers and the respective LEDs are often formed on other substrates that match the characteristics of GaN. Sapphire (Al₂O₃) is a commonly used substrate material. It was observed, however, that sapphire has a low thermal conductivity. As a result, the heat generated by LEDs cannot be dissipated efficiently through sapphire substrates.

### SUMMARY

In accordance with one aspect, multiple through-substrate vias (TSVs) are used to make electrical connections for an LED formed over a substrate. A first TSV extends through the substrate from a back surface of the substrate to the front surface of the substrate and includes a first TSV conductor that electrically connects to a first cladding layer of the LED. A second TSV extends through the substrate and the active layer of the LED from the back surface of the substrate to a second cladding layer or an indium tin oxide (ITO) layer. The second TSV includes an isolation layer that electrically isolates a second TSV conductor from the first cladding layer and the active layer. Additionally, dummy TSVs may be formed to conduct heat away from the LED through a package substrate. The dummy TSVs may be formed simultaneously with the first TSV or simultaneously with the second TSV. An ohmic contact layer may be formed to more uniformly distribute a current that is used for driving the LED. An ITO layer may be formed over the ohmic contact layer. A reflector may be formed on the substrate, with openings formed in the reflector to allow spaces for the first TSV, the second TSV, and the dummy TSVs.

Other embodiments are also disclosed.

### BRIEF DESCRIPTION OF THE DRAWINGS

For a more complete understanding of the embodiments, and the advantages thereof, reference is now made to the following descriptions taken in conjunction with the accompanying drawings, in which:

FIGS. 1 through 8 are cross-sectional views and bottom views of intermediate stages in the manufacturing of a light-emitting device (LED) in accordance with various embodiments; and

FIGS. 9 through 11 illustrate cross-sectional views of intermediate stages in the manufacturing of an LED in accordance with various embodiments.

### DETAILED DESCRIPTION OF ILLUSTRATIVE EMBODIMENTS

The making and using of the embodiments of the disclosure are discussed in detail below. It should be appreciated, however, that the embodiments provide many applicable inventive concepts that can be embodied in a wide variety of specific contexts. The specific embodiments discussed are merely illustrative and do not limit the scope of the disclosure.

A device including a light-emitting device (LED) and the method of forming the same are provided. The intermediate stages of manufacturing an LED device in accordance with an embodiment are illustrated. The variations of the embodiment are then discussed. Throughout the various views and illustrative embodiments, like reference numbers are used to designate like elements.

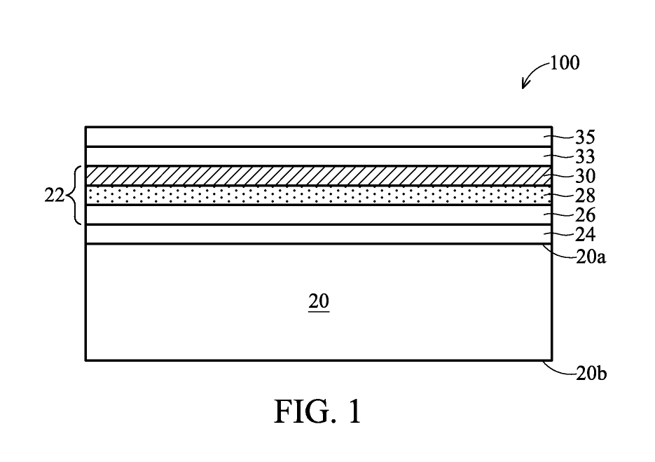

Referring to FIG. 1, wafer 100, which includes LED 22 formed on substrate 20, is formed. In an embodiment, substrate 20 is formed of sapphire (Al₂O₃). In other embodiments, substrate 20 comprises layers formed of compound semiconductor materials comprising group-III and group-V elements, or also known as III-V compound semiconductor materials. In yet other embodiments, substrate 20 may be a silicon substrate, a silicon carbide substrate, a silicon substrate with a silicon carbide layer thereon, a silicon germanium substrate, or a substrate formed of other applicable semiconductor materials. Throughout the description, the side of substrate 20 facing up is referred to as a front side, with surface 20a referred to as a front surface, and surface 20b on the back side referred to as a back surface.

Buffer layer 24 is formed over, and possibly contacts, substrate 20. Buffer layer 24 may also be referred to as a nucleation layer, which may be epitaxially grown at a lower temperature than the overlying layer 26. In an embodiment, buffer layer 24 comprises a same III-V compound semiconductor material as the overlying layer 26. Cladding layer 26 is formed on buffer layer 24, and may be formed of GaN, GaAsP, GaPN, AlInGaAs, GaAsPN, or AlGaAs, or combinations thereof. Cladding layer 26 is doped with an impurity of a first conductivity type, such as n-type. Multiple quantum wells (MQWs) 28, which may also be referred to as an active layer, are formed on cladding layer 26. MQWs 28 may be formed of, for example, InGaN, and emit light. Cladding layer 30 is further formed on active layer 28, and is of a second conductivity type opposite the first conductivity type. In an exemplary embodiment, cladding layer 30 is a GaN layer doped with a p-type impurity. According to some embodiments, an optional ohmic contact layer 33 is formed on cladding layer 30, followed by the optional formation of optional indium tin oxide (ITO) layer 35, which is conductive. Ohmic contact layer 33 and/or ITO layer 35 may be formed in large LED chips, but may be, or may not be, omitted in small LED chips. Ohmic contact layer 33 may be formed of GaAs or other applicable materials, such as AuGe, PdGe, or the like. Further, Ohmic contact layer 33 may be a composite layer, including a titanium layer on a platinum layer, which is further on a gold layer. Alternatively, only one of ohmic contact layer 33 and ITO layer 35 is formed on cladding layer 30. The formations of layers 26, 28, and 30 are known in the art, and hence are not repeated herein. In an exemplary embodiment, the formation methods of layers 26, 28, and 30 may include epitaxial growth. Throughout the description, layers 26, 28, and 30 are referred to together as LED 22.

It is realized that LED 22 may have many designs and FIG. 1 only shows an exemplary version among the available variations. For example, the materials of each of the layers 26, 28, and 30 may be different from the above-discussed materials, and may be ternary III-V compound semiconductor materials. Also, cladding layer 26 may be doped with a p-type impurity, while cladding layer 30 may be doped with an n-type impurity.

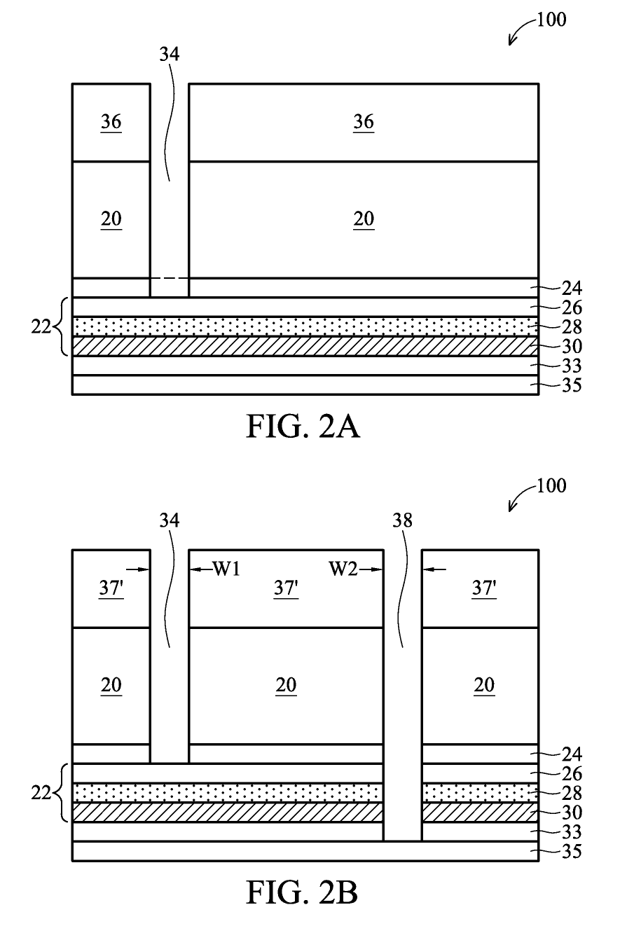

Referring to FIG. 2A, TSV opening 34 is formed from the bottom of substrate 20. In an embodiment, photoresist 36 is formed to cover substrate 20, with a portion of substrate 20 being exposed. The exposed portion of substrate 20 is then etched, for example, using dry etching. Photoresist 36 is then removed. In alternative embodiments, TSV opening 34 is formed using laser drilling. TSV opening 34 may stop at layer 26. In some embodiments, the formation of TSV opening 34 is stopped when cladding layer 26 is reached. Alternatively, the formation of TSV opening 34 is stopped when buffer layer 24 is exposed, wherein the dotted line in TSV opening 34 represents the respective bottom. Photoresist 36 is then removed.

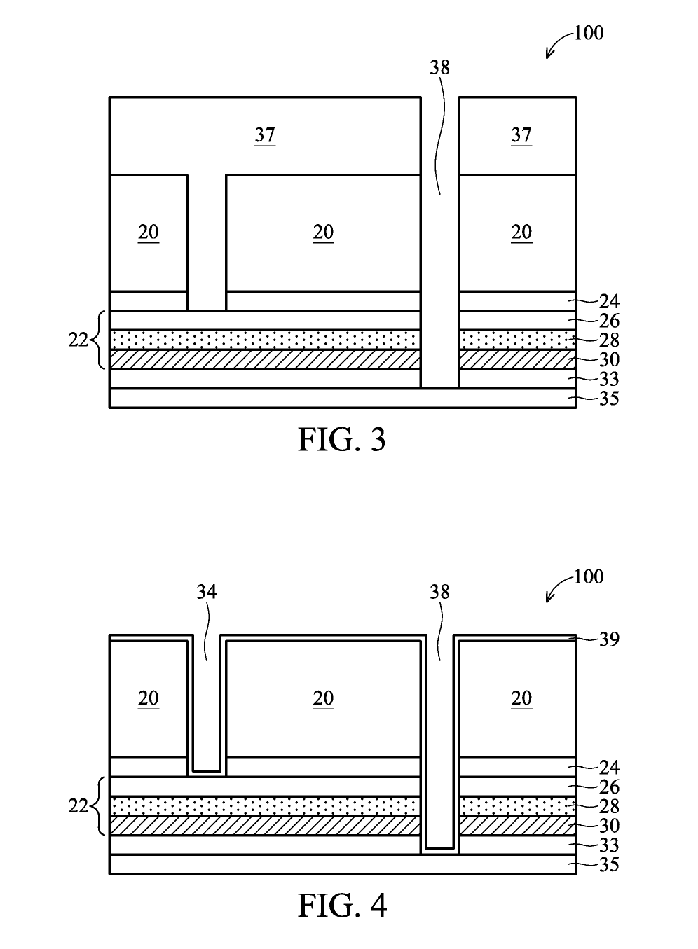

FIG. 3 illustrates the formation of TSV opening 38. Similar to the formation of TSV opening 34, TSV opening 38 may be formed by etching, using photoresist 37 as a mask, or formed using laser drilling. TSV opening 38 penetrates through cladding layer 26 and active layer 28, so that p-GaN cladding layer 30 is at least exposed, or partial or fully etched/drilled. When ohmic contact layer 33 and/or the ITO layer 35 are used, TSV opening 38 may contact (or penetrate) ohmic contact layer 33 or ITO layer 35. Photoresist 37 is then removed.

In alternative embodiments, instead of using two masking steps to form TSV openings 34 and 38, TSV openings 34 and 38 may be formed simultaneously by etching, using a single masking step. In these embodiments, as shown in FIG. 2B, a mask (such as photoresist 37′) is formed and patterned, with openings formed in photoresist 37′ at locations where TSV openings 34 and 38 are formed. The horizontal size W1 of the first opening, which is for forming TSV opening 34, however, may be different from the horizontal size W2 of the second opening, which is for forming TSV opening 38. Due to the pattern loading effect, the resulting TSV openings 34 and 38 may have different depths, as desired.

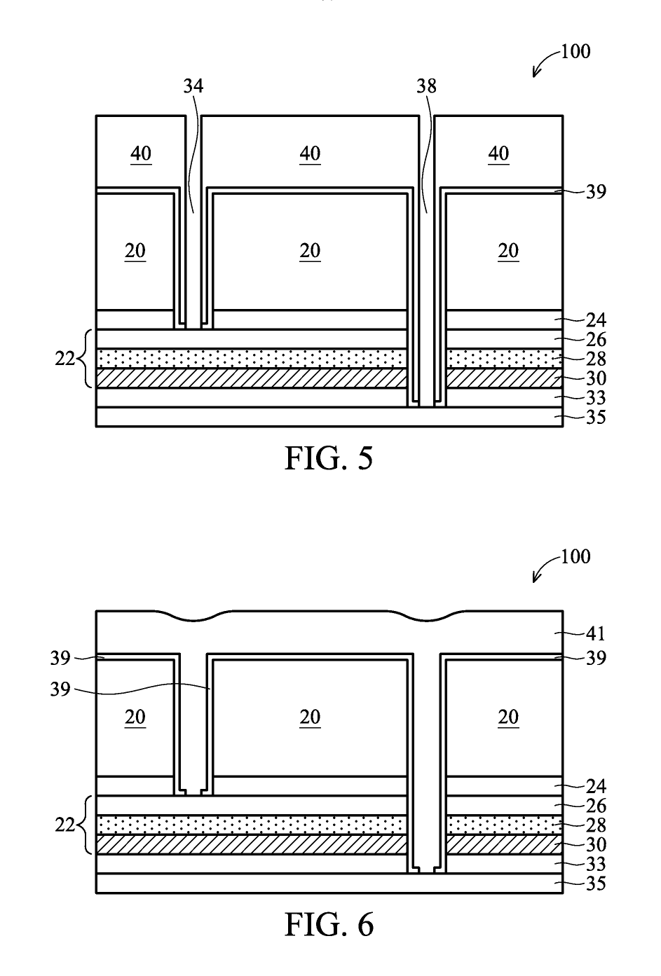

Referring to FIG. 4, isolation layer 39 is formed on the sidewalls and bottoms of TSV openings 34 and 38, and may be formed as a conformal layer. In an embodiment, isolation layer 39 is formed of silicon nitride, although it may also be formed of other commonly used dielectric materials, such as silicon oxide, silicon oxynitride, and/or the like. Next, as shown in FIG. 5, mask 40, which may be a photoresist layer, is formed to cover isolation layer 39. Mask 40 is patterned so that the portions of isolation layer 39 at the bottoms of TSV openings 34 and 38 are exposed, while the sidewall portions of isolation layer 39 in TSV openings 34 and 38 are protected. The exposed bottom portions of isolation layer 39 are then etched (wherein a wet etching may be used) to expose the underlying layers 24/26 and 30. In alternative embodiment, a dry etch, for example, using Ar plasma (not shown), may be used to remove the bottom portions of isolation layer 39, wherein no photo mask is needed for the dry etch.

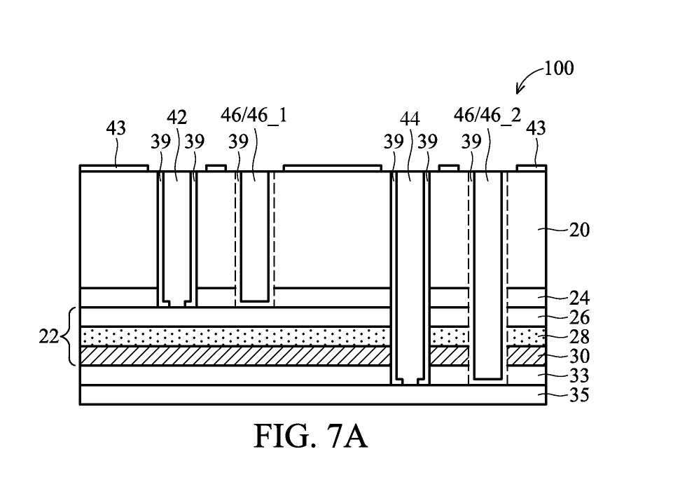

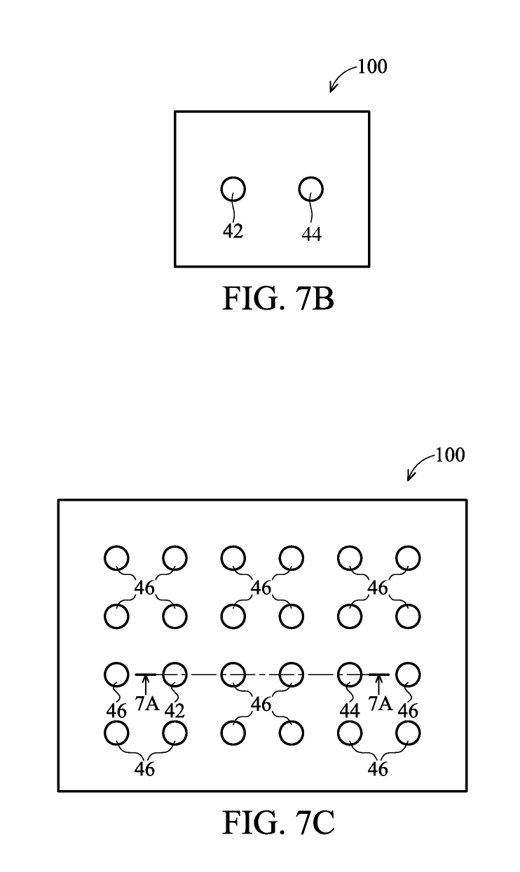

Referring to FIGS. 6 and 7A, mask 40 is removed, and openings 34 and 38 are filled with a metallic material, such as copper, aluminum, tungsten, and combinations thereof. A planarization, such as a chemical mechanical polish (CMP) is then performed to remove excess metallic material on substrate 20. In alternative embodiments, a back lapping or backside grinding is applied instead of a CMP step. The remaining portions of the metallic material form TSVs 42 and 44, as shown in FIG. 7A. Isolation layer 39 may be circumferential, peripheral, encircling, and surrounding (to) one of TSVs 42 and 44. TSVs 42 and 44 may have one of the many shapes (viewed from the top) including round, rectangular, etc., as photolithography places no limitation on the shape.

FIG. 7B illustrates an exemplary bottom view of a portion of wafer 100, wherein TSVs 42 and 44 are exposed through the bottoms of wafer 100, and are electrically connected to the p-type and n-type cladding layers 26 and 30 that are on an opposite side of active layer 28 (FIG. 7A). Accordingly, a voltage may be applied on TSVs 42 and 44 to activate LED 22 so that light is emitted from active layer 28. FIG. 7C illustrates a bottom view of wafer 100 in accordance with various embodiments, wherein a plurality of TSVs 42, 44 and 46 are formed. The cross-sectional view of the structure shown in FIG. 7A may be obtained from the plane crossing line 7A-7A in FIG. 7C. In addition to TSVs 42 and 44, TSVs 46 may be formed and used as dummy TSVs (alternatively referred to as thermal TSVs) that are used for dissipating heat, while no current flows through TSVs 46 during LED operation.

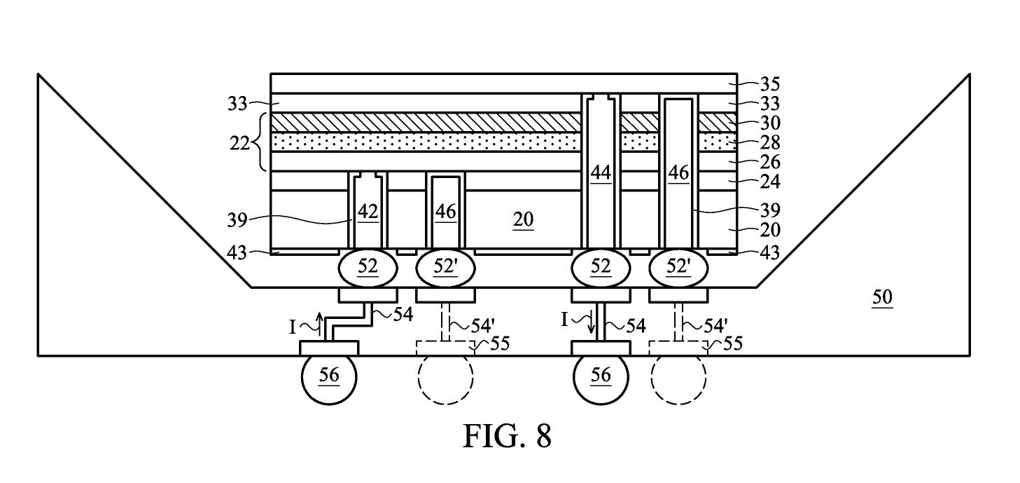

In an embodiment, as shown in FIG. 7A, dummy TSVs 46 are electrically insulated from cladding layers 26 and 30 by isolation layer 39. In alternative embodiments, thermal TSVs 46 are electrically connected to cladding layers 26 and/or 28 through openings in the respective portions of isolation layer 39, wherein the openings may be formed in the step shown in FIG. 5. However, no current flows through thermal TSVs 46 when a voltage is applied between TSVs 42 and 44. Thermal TSVs 46 function to dissipate the heat generated in LED 22. An exemplary embodiment for the connection of thermal TSVs 46 is shown in FIG. 8, which illustrates that, regardless whether thermal TSVs 46 are electrically connected to cladding layers 26 and 30, thermal TSVs 46 are not connected to an external electrode on package substrate 50 and hence cannot carry currents.

In some embodiments, thermal TSVs 46 are formed simultaneously when TSV 42 is formed, and the respective thermal TSV 46 is shown as TSV 46_1 in FIG. 7A. In alternative embodiments, thermal TSVs 46 are formed simultaneously when TSV 44 is formed, and the respective thermal TSV 46 is shown as TSV 46_2 in FIG. 7A. In yet other embodiments, some of thermal TSVs 46 are formed when TSV 42 is formed, while the remaining ones are formed when TSV 44 is formed.

FIG. 7A also illustrates the formation of an optional reflector 43, which may be formed of metal, such as aluminum, copper, gold, silver, or alloys thereof. Openings are formed in reflector 43 so that TSVs 42 and 44 and dummy TSVs 46 are exposed and are reachable. In an embodiment, reflector 43 is formed by printing. In alternative embodiments, reflector 43 is formed by depositing a blanket reflector layer and then removing undesirable portions from the reflector layer, with the remaining portions forming reflector 43.

Referring to FIG. 8, LED 22 and the respective TSVs 42 and 44 may be sawed from wafer 100 and bonded onto package substrate 50, for example, through flip-chip bonding. Package substrate 50 may include electrical routes 54 that connect TSVs 42 and 44 through solder bumps 52. A voltage may be applied to LED 22 through solder balls 56, through which current I flows through LED 22. On the other hand, dummy solder bumps 52′ may connect bond package substrate 50 to thermal TSVs 46. However, no current flows through (and possibly, no voltage is applied on) dummy solder bumps 52′. Rather, thermal TSVs 46 and dummy solder bumps 52′ are only used for dissipating heat. For better heat-dissipating ability, dummy TSVs 54′ may be formed in package substrate 50, so that the heat generated in LED 22 may be conducted to the dummy TSVs 54′, through dummy bumps 55, and then to an outside component, such as a heat sink (not shown).

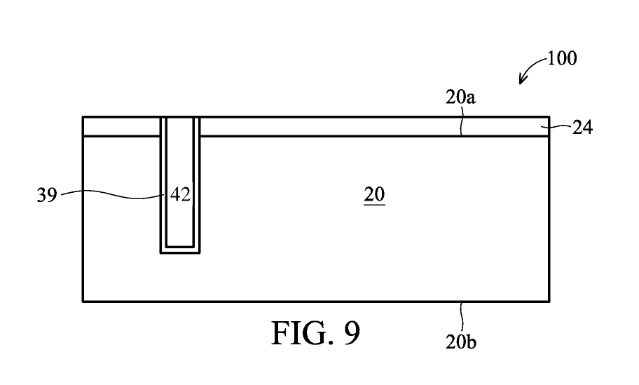

FIGS. 9-11 illustrate the intermediate stages in the formation of an LED chip comprising TSVs in accordance with an alternative embodiment, wherein TSVs 42 and 44 are formed from the front side of substrate 20. Unless specified otherwise, like elements in this embodiment are essentially the same as in the preceding embodiments, and hence the details of the materials and the formation methods may not be repeated herein.

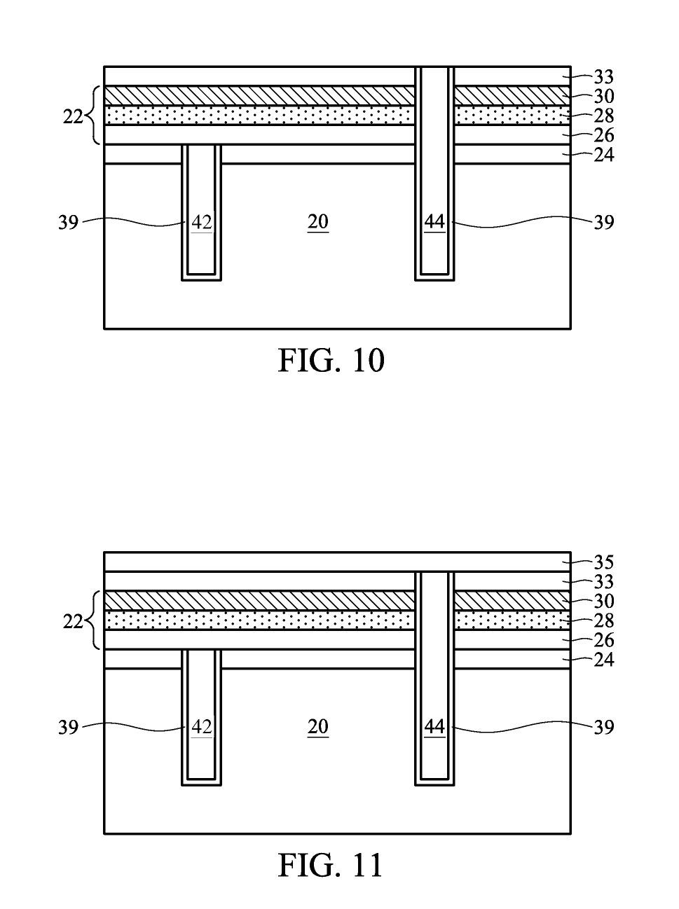

Referring to FIG. 9, substrate 20 is provided, and TSV 42 and isolation layer 39 are formed in substrate 20. TSV 42 may be formed before or after the formation of buffer layer 24. The formation of TSV 42 may be accompanied by the simultaneous formation of thermal TSVs 46/46_1 (not shown in FIG. 9, pleaser refer to FIGS. 7A and 7C). Next, as shown in FIG. 10, cladding layer 26, active layer 28, cladding layer 30, and optionally ohmic contact layer 33 are formed. TSV 44 is then formed to penetrate through ohmic contact layer 33, active layer 28, cladding layer 26, buffer layer 24, and extending into substrate 20. The formation of TSV 44 may be accompanied by the simultaneous formation of thermal TSVs 46/46_2 (not shown in FIG. 10, pleaser refer to FIGS. 7A and 7C). Following the formation of TSV 44, ITO layer 35 may be formed, as shown in FIG. 11. The back side of substrate 20 may then be grinded until TSVs 42 and 44 are exposed.

The embodiments may be packaged easily using flip-chip bonding, as shown in FIG. 8. Further, the process steps may require as few as two masks, and hence the manufacturing cost is low. In addition, it is possible to add thermal TSVs to improve the heat-dissipation ability of the LED chip.

Although the embodiments and their advantages have been described in detail, it should be understood that various changes, substitutions, and alterations can be made herein without departing from the spirit and scope of the embodiments as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure, processes, machines, manufacture, compositions of matter, means, methods, or steps, presently existing or later to be developed, that perform substantially the same function or achieve substantially the same result as the corresponding embodiments described herein may be utilized according to the disclosure. Accordingly, the appended claims are intended to include within their scope such processes, machines, manufacture, compositions of matter, means, methods, or steps. In addition, each claim constitutes a separate embodiment, and the combination of various claims and embodiments are within the scope of the disclosure.

What is claimed is:

1. A device comprising:
a substrate comprising a front surface and a back surface;
a light-emitting device (LED) on the substrate, wherein the LED comprises:
a first cladding layer;
an active layer over the first cladding layer; and
a second cladding layer over the active layer;
a first through-substrate via (TSV) extending from the back surface of the substrate to the surface of the substrate, the first TSV comprising a first TSV conductor; and
a second TSV extending from the back surface of the substrate to the second cladding layer, wherein the second TSV comprises a second TSV conductor and an isolation layer, and wherein the isolation layer electrically isolates the second TSV conductor in the second TSV from the substrate, the first cladding layer and the active layer.

2. The device of claim 1, wherein the LED further comprises an ohmic contact layer over the second cladding layer and an indium tin oxide (ITO) layer over the ohmic contact layer.

3. The device of claim 1, wherein the first cladding layer and the second cladding layer comprise a material selected from the group consisting essentially of GaN, AlInGaP, GaAsP, GaP, and combinations thereof.

4. The device of claim 1, wherein the second cladding layer comprises GaN.

5. The device of claim 1 further comprising a plurality of dummy TSVs in the substrate.

6. The device of claim 1, wherein the substrate comprises a material selected from the group consisting essentially of sapphire, SiC, GaAs, silicon, SiGe, and combinations thereof.

7. The device of claim 1, wherein the second TSV at least partially penetrates the second cladding layer.

8. The device of claim 1, wherein the first TSV conductor in the first TSV electrically contacts the first cladding layer and is not electrically coupled to the active layer.

9. The device of claim 1, wherein the first TSV further comprises a circumferential isolation layer.

10. A device comprising:
a substrate comprising a first side and a second side opposite the first side;
a light-emitting device (LED) on the substrate, wherein the LED comprises:
a first group-III/V compound layer doped with a first impurity of a first conductivity type over the substrate;
an active layer over the first group-III/V compound layer; and
a second group-III/V compound layer doped with a second impurity of a second conductivity type opposite the first conductivity type over the active layer;
a first through-substrate via (TSV) extending from the first side of the substrate to the first group-III/V compound layer, the first TSV comprising a first TSV conductor; and
a second TSV extending from the first side of the substrate to the second group-III/V compound layer, the second TSV comprising a second TSV conductor and an isolation layer encircling the second TSV conductor, wherein the first and second TSVs are configured to accept a voltage for activating the LED to emit light.

11. The device of claim 10 further comprising dummy TSVs in the substrate.

12. The device of claim 10 further comprising a package substrate bonded onto the LED.

13. The device of claim 12, wherein the package substrate is configured not to pass currents to the dummy TSVs.

14. The device of claim 10, wherein the first TSV further comprises an isolation layer separating the first TSV from the substrate.

15. The device of claim 10, wherein the substrate comprises a material selected from the group consisting essentially of sapphire, SiC, Si, SiGe, GaAs, and combinations thereof.

16. A device comprising:
a substrate;
a light-emitting device (LED) over the substrate;
a first and a second through-substrate via (TSV) penetrating the substrate and extending to, and stopping at, layers on opposite sides of an active layer, wherein the first and the second TSVs are configured to conduct a voltage to the LED;
a first dummy TSV penetrating the substrate;
a package substrate bonded onto the substrate, wherein the package substrate comprises:
a third and a fourth TSV electrically coupled to the first and the second TSVs, respectively; and
a dummy pad electrically coupled to the first dummy TSV.

17. The device of claim 16, wherein the package substrate further comprises a second dummy TSV in the package substrate and electrically coupled to the first dummy TSV through a dummy bond.

18. The device of claim 16, wherein the first dummy TSV penetrates the active layer of the LED.

19. The device of claim 16, wherein the first dummy TSV does not penetrate any active layer of the LED.

20. A method of forming a device, the method comprising:
providing a substrate;
forming a light-emitting device (LED) comprising:
forming a first cladding layer over the substrate;
forming an active layer over the first cladding layer; and
forming a second cladding layer over the active layer;
forming a first opening extending to the first cladding layer;
forming a second opening extending at least to the second cladding layer;
filling a circumferential isolation layer in each of the first and second openings;
removing a bottom portion of the circumferential isolation layer of the first opening;
removing a bottom portion of the circumferential isolation layer of the second opening; and
filling conductive materials into the first and the second openings to form a first through-substrate via (TSV) and a second TSV, respectively.

21. The method of claim 20 further comprising forming an ohmic contact layer over the second cladding layer and forming an indium tin oxide (ITO) layer over the ohmic contact layer.

22. The method of claim 20, wherein the step of forming the first opening is performed before the step of forming the first cladding layer, and the step of forming the second opening is performed after the step of forming the active layer.

23. The method of claim 20 further comprising, when the step of forming the first TSV is performed, simultaneously forming dummy TSVs.

24. The method of claim 23 further comprising, when the step of forming the second TSV is performed, simultaneously forming additional dummy TSVs.

25. The method of claim 20, wherein the first TSV contacts the first cladding layer and does not contact the active layer.

26. The method of claim 21, wherein the second TSV contacts the ITO layer and does not contact the first cladding layer or the active layer.
